(19) United States
(12) Patent Application Publication
(10) Pub. No.: US 2022/0052694 A1
(43) Pub. Date: Feb. 17, 2022

(54) ISOLATION CIRCUIT WITHOUT ROUTED PATH COUPLED TO ALWAYS-ON POWER SUPPLY

(71) Applicant: MediaTek Singapore Pte. Ltd., Singapore (SG)

(72) Inventors: Varinder Kumar, Bangalore (IN); Heerak Bandopadhyay, Bangalore (IN); Girishankar Gurumurthy, Bangalore (IN); Aakash Srivastava, Bangalore (IN); Ramesh SrinivasRao Guzar, Singapore (SG)

(21) Appl. No.: 16/994,673

(22) Filed: Aug. 17, 2020

(51) Int. Cl. H03K 19/20

(52) U.S. Cl. CPC H03K 19/20

(57) ABSTRACT

An isolation circuit includes an inverter and a NOR-gate. The inverter includes an input terminal used to receive an input signal, an output terminal used to output an output signal according to the input signal, and a power terminal coupled to a power supply. The output signal is complementary to the input signal. The NOR-gate is used to perform a logic NOR operation using the output signal and an isolation control signal to generate a result signal. The NOR-gate includes a first input terminal coupled to the output terminal of the inverter for receiving the output signal, a second input terminal for receiving the isolation control signal, and an output terminal for outputting the result signal.

### BACKGROUND

In the field of integrated-circuit (IC) design, low power designs are widely used these days to meet the power requirements of the chip without hindering the performance. In a low power design, some power supply nets are switchable and can be turned off, and some power supply nets are always on.

FIG. 1 illustrates that a signal is transmitted from a power domain PD1 to a power domain PD2 according to prior art. As shown in FIG. 1, the power domains PD1 and PD2 are respectively powered by power supplies DVDD1 and DVDD2. The power supplies DVDD1 and DVDD2 are powered by an always-on power supply RVDD. The power supplies DVDD1 and DVDD2 are respectively connected to the power supply RVDD through a switch SW1 and a switch SW2.

When the switch SW1 is turned off and the switch SW2 is turned on, the power domain PD1 is not powered, and the power domain PD2 is powered. Hence, the power domains PD1 and PD2 are respectively regarded as an OFF domain and an ON domain.

A signal 51 is transmitted from a logic gate 111 of the power domain PD1 to the power domain PD2. When the power domain PD1 is not powered, the logic gate 111 is in a transient stage, so the signal 51 has an indefinite value. This will lead to functionality failure or high leakage current. To reduce this problem, an isolation circuit (a.k.a. isolation cell) 112 is embedded in the OFF domain (e.g., power domain PD1) and coupled to the logic gate 111. The isolation circuit 112 receives the signals 51 and SISO and provides a signal S2 accordingly.

When the power domain PD1 is powered to the ON domain, the signal SISO has a predetermined value (e.g., 0), and the signal S2 has the same value as the signal 51. When the power domain PD1 is not powered to the OFF domain, the signal SISO has a predetermined value (e.g., 1), and the signal S2 has a predetermined value (e.g., 0) instead of an unwanted indefinite value.

Although the structure of FIG. 1 is feasible, as shown in FIG. 1, the isolation circuit 112 must be coupled to an always-on power supply such as the power supply RVDD. Hence, related paths are unavoidable and lead to a congestion problem of place-and-route (P&R). In addition, a traditional isolation circuit often includes at least eight transistors, it is difficult to simplify the structure of the isolation circuit.

### SUMMARY

An embodiment provides an isolation circuit including an inverter and a NOR-gate. The inverter includes an input terminal configured to receive an input signal, an output terminal configured to output an output signal according to the input signal, and a power terminal coupled to a power supply. The output signal is complementary to the input signal. The NOR-gate is used to perform a logical NOR operation using the output signal and an isolation control signal to generate a result signal. The NOR-gate includes a first input terminal coupled to the output terminal of the inverter and configured to receive the output signal, a second input terminal configured to receive the isolation control signal, and an output terminal configured to output the result signal.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates that a signal is transmitted from an OFF domain to an ON domain according to prior art.

FIG. 2 illustrates an isolation circuit according to an embodiment.

FIG. 3 illustrates the structure of the NOR-gate of FIG. 2.

FIG. 4 illustrates the structure of the inverter of FIG. 2.

FIG. 5 illustrates a place-and-route layout of the isolation circuit of FIG. 2.

FIG. 6 illustrates a first power domain and a second power domain placed along a vertical direction where an array of isolation circuits is embedded in the first power domain.

FIG. 7 illustrates a layout of the isolation circuit used in the scenario of FIG. 6.

FIG. 8 illustrates a first power domain and a second power domain placed along a horizontal direction where an array of isolation circuits is embedded in the first power domain.

FIG. 9 illustrates a layout of the isolation circuit used in the scenario of FIG. 8.

### DETAILED DESCRIPTION

Here in the text, a power domain is regarded as an ON domain when the power domain is powered; the power domain is regarded as an OFF domain when the power domain is not powered; a high voltage level may be corresponding to a value 1; and a low voltage level may be corresponding to a value 0.

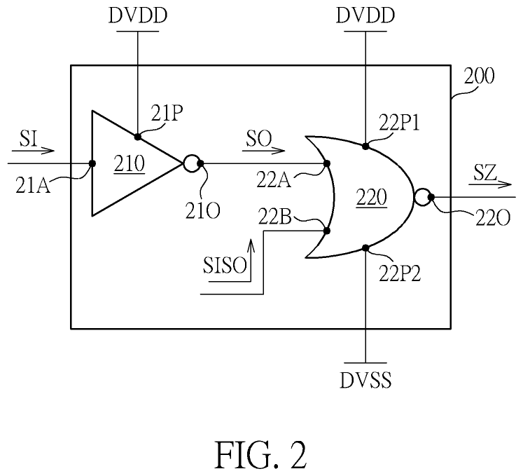

In order to reduce the problem of congestion of place-and-route, and decrease the number of transistors in an isolation circuit, an isolation circuit 200 is proposed according to an embodiment as shown in FIG. 2.

The isolation circuit 200 may include an inverter 210 and a NOR-gate 220. The inverter 210 may include an input terminal 21A used to receive an input signal SI, an output terminal 210 used to output an output signal SO according to the input signal SI, and a power terminal 21P coupled to a power supply DVDD. The output signal SO may be complementary to the input signal SI.

The NOR-gate 220 may be used to perform a logic NOR operation using the output signal SO and an isolation control signal SISO to generate a result signal SZ. The NOR-gate may include a first input terminal 22A, a second input terminal 22B and an output terminal 220.

The first input terminal 22A is coupled to the output terminal of the inverter 210 and used to receive the output signal SO. The second input terminal 22B is used to receive the isolation control signal SISO. The output terminal 220 is used to output the result signal SZ.

As shown in FIG. 2, the NOR-gate 220 may further include a first power terminal 22P1 coupled to the power supply DVDD. The NOR-gate 220 may further include a second power terminal 22P2 coupled to a reference voltage source DVSS. The reference voltage source DVSS may have a low voltage level. For example, the reference voltage source DVSS may be (but not limited to) a ground terminal.

According to an embodiment, the power supply DVDD may be switchable instead of being always on. For example, when the power supply DVDD is turned on, the inverter 210 and the NOR-gate 220 may be powered; and when the power supply DVDD is turned off, the inverter 210 and the NOR-gate 220 may not be powered.

The operations of the isolation circuit 200 may be described as Table 1. The result signal SZ is at a low voltage level (e.g., denoted as 0) when the input signal SI is at the low voltage level and the isolation control signal SISO is at the low voltage level.

The result signal SZ is at a high voltage level (e.g., denoted as 1) when the input signal SI is at the high voltage level and the isolation control signal SISO is at a low voltage level.

The result signal SZ is at a low voltage level when the isolation control signal SISO is at a high voltage level.

TABLE 1

| SI | SO | SISO | SZ | Note |
|---|---|---|---|---|
| 0 | 1 | 0 | 0 | The domain where the isolation circuit |
| 1 | 0 | 0 | 1 | 200 is embedded is powered. |
| 0 | 1 | 1 | 0 | The domain where the isolation circuit |
| 1 | 0 | 1 | 0 | 200 is embedded is not powered. |

According to an embodiment, the isolation control signal SISO is at the low voltage level when the power supply DVDD is powered; and the isolation control signal SISO is at the high voltage level when the power supply DVDD is not powered. In other words, when the domain the isolation circuit 200 is not powered and thus is in an OFF domain, the isolation control signal SISO has the high voltage value.

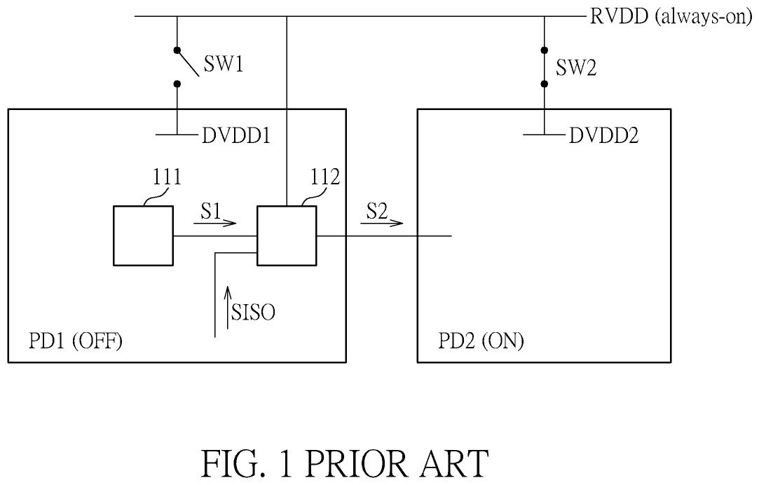

As shown in Table 1, when the isolation circuit 200 is in an OFF domain, the isolation circuit 200 may output the result signal SZ having a predetermined value (e.g., 0) instead of an unwanted indefinite voltage level. Regarding FIG. 2, because it is unnecessary for the isolation circuit 200 to be coupled to an always-on power supply such as the power supply RVDD shown in FIG. 1, the conductive paths and layers of place-and-route can be simplified, and the congestion problem can be reduced.

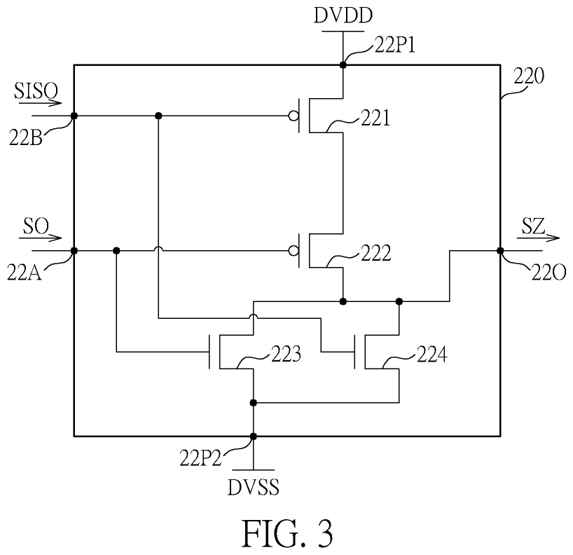

FIG. 3 illustrates the structure of the NOR-gate 220 of FIG. 2. As shown in FIG. 3, the NOR-gate 220 may further include a first transistor 221, a second transistor 222, a third transistor 223 and a fourth transistor 224.

Regarding FIG. 2 and FIG. 3, the first transistor 221 may include a first terminal, a second terminal and a control terminal, where the first terminal is coupled to the power supply DVDD, and the control terminal is coupled to the second input terminal 22B of the NOR-gate 220 to receive the isolation control signal SISO.

The second transistor 222 may include a first terminal, a second terminal and a control terminal, where the first terminal is coupled to the second terminal of the first transistor 221, the second terminal is coupled to the output terminal 220 of the NOR-gate 220, and the control terminal is coupled to the first input terminal 22A of the NOR-gate 220 to receive the output signal SO.

The third transistor 223 may include a first terminal, a second terminal and a control terminal, where the first terminal is coupled to the output terminal 220 of the NOR-gate 220, and the control terminal is coupled to the first input terminal 22A of the NOR-gate 220.

The fourth transistor 224 may include a first terminal, a second terminal and a control terminal, where the first terminal is coupled to the output terminal 220 of the NOR-gate 220, and the control terminal is coupled to the second input terminal 22B of the NOR-gate 220.

As shown in FIG. 3, the second terminal of the third transistor 223 may be coupled to the second power terminal 22P2 of the NOR-gate 220. The second terminal of the fourth transistor 224 may be coupled to the second power terminal 22P2 of the NOR-gate 220.

According to an embodiment, the first transistor 221 and the second transistor 222 may be P-type transistors, and the third transistor 223 and the fourth transistor 224 may be N-type transistors.

In each of the first transistor 221 and the second transistor 222, the first terminal, the second terminal and the control terminal may be a source terminal, a drain terminal and a gate terminal respectively. In each of the third transistor 223 and the fourth transistor 224, the first terminal, the second terminal and the control terminal may be a drain terminal, a source terminal and a gate terminal respectively.

Regarding FIG. 2 and FIG. 3, when the isolation circuit 200 is in an OFF domain, the isolation control signal SISO may be at a high voltage level to turn on the fourth transistor 224. In this scenario, the output terminal 220 of the NOR-gate 220 may be electrically connected to the reference voltage source DVSS, and the result signal SZ may have the same voltage level as the reference voltage source DVSS. Hence, the result signal SZ may be corresponding to the value 0 as shown in Table 1.

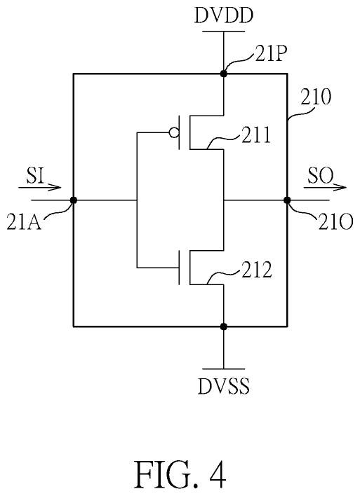

FIG. 4 illustrates the structure of the inverter 210 of FIG. 2. Regarding FIG. 2 and FIG. 3, the inverter 210 may include a first transistor 211 and a second transistor 212. The first transistor 211 may include a first terminal, a second terminal and a control terminal, where the first terminal is coupled to the power terminal 21P of the inverter 210, the second terminal is coupled to the output terminal 210 of the inverter 210, and the control terminal is coupled to the input terminal 21A of the inverter 210. The second transistor 212 may include a first terminal, a second terminal and a control terminal, where the first terminal is coupled to the output terminal 210 of the inverter 210, the second terminal may be coupled to the reference voltage source DVSS or another reference voltage source, and the control terminal is coupled to the input terminal 21A of the inverter 210.

According to an embodiment, the first transistor 211 of the inverter 210 may be a P-type transistor, and the second transistor 212 of the inverter 210 may be an N-type transistor.

In the first transistor 211, the first terminal, the second terminal and the control terminal may be a source terminal, a drain terminal and a gate terminal respectively. In the second transistor 212, the first terminal, the second terminal and the control terminal may be a drain terminal, a source terminal and a gate terminal respectively.

As shown in FIG. 2 to FIG. 4, the inverter 210 may include two transistors, and the NOR-gate 220 may include four transistors. Hence, the isolation circuit 200 may include as few as six transistors while an isolation circuit of prior art must have at least eight transistors.

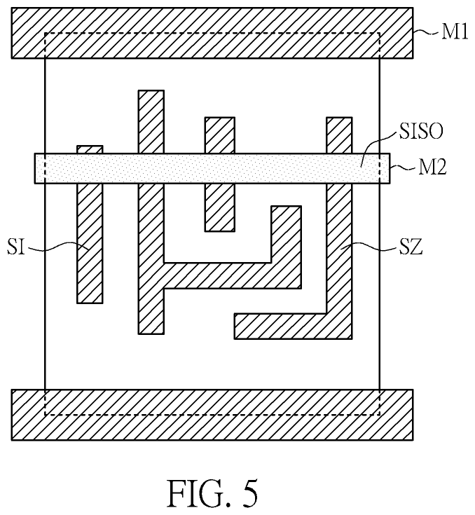

FIG. 5 illustrates a place-and-route layout of the isolation circuit 200 of FIG. 2. In FIG. 5, some details are omitted. As shown in FIG. 2, the conductive part(s) used to receive the input signal SI and transmit the result signal SISO may be implemented on a first metal layer M1. The conductive part(s) used to receive the isolation control signal SISO may be implemented on a second metal layer M2. The second metal layer M2 may be placed above or below the first metal layer M1. FIG. 5 is merely an example instead of limiting the layout of the isolation circuit 200.

As shown in FIG. 5, it is unnecessary to have a conductive part coupled to an always-on power supply (e.g., RVDD In FIG. 1). Hence, by means of the isolation circuit 200, the layout and the place-and-route process can be simplified, and the problem of congestion can be reduced.

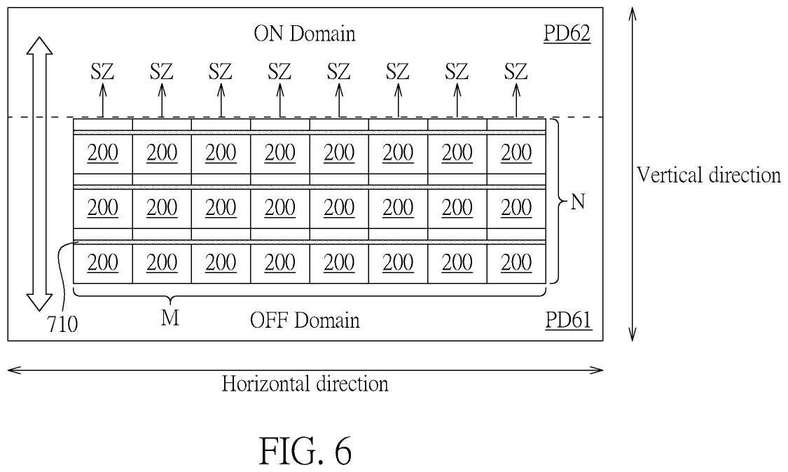

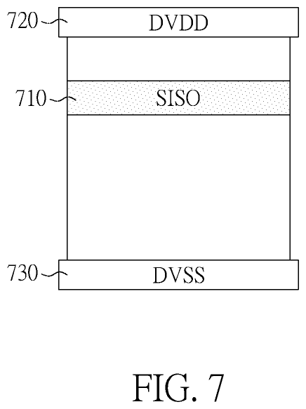

FIG. 6 illustrates a power domain PD61 and a power domain PD62 where an array of isolation circuits 200 is embedded in the power domain PD61. FIG. 7 illustrates a layout of the isolation circuit 200 used in the scenario of FIG. 6.

In FIG. 6, each of the isolation circuits 200 is embedded in the power domain PD61, and each of the result signals SZ is transmitted to a circuit in the power domain PD62. The power domain PD61 is switchable and can be powered off when the power domain PD62 is powered on. In other words, the power domains PD61 and PD62 can respectively be an OFF domain and an ON domain.

As shown in FIG. 6, the power domain PD61 and the power domain PD62 may be placed along a vertical direction. As shown in FIG. 7, the isolation circuit 200 of FIG. 6 may include a first conductive portion 710 used to receive the isolation control signal SISO described in FIG. 2 to FIG. 4. The first conductive portion 710 may be routed along a horizontal direction substantially perpendicular to the vertical direction.

As shown in FIG. 7, the isolation circuit 200 of FIG. 6 may further include a second conductive portion 720 coupled to the power supply DVDD (mentioned in FIG. 2 to FIG. 4), and the second conductive portion 720 may be routed along the horizontal direction.

As shown in FIG. 7, the isolation circuit 200 of FIG. 6 may further include a third conductive portion 730 coupled to the reference voltage source DVSS (mentioned in FIG. 2 to FIG. 4), and the third conductive portion 730 may be routed along the horizontal direction.

In FIG. 6 and FIG. 7, the first conductive portion 710 and the second conductive portion 720 may be formed on different conductive layers. For example, the first conductive portion 710 can be formed on a second metal layer while the second conductive portion 720 is formed on a first metal layer below the second metal layer.

As shown in FIG. 6 and FIG. 7, the array of the isolation circuits 200 may include M×N isolation circuits 200 including M columns and N rows of isolation circuits 200. The first conductive portions 710 of the isolation circuits 200 in the same row may be coupled to one another.

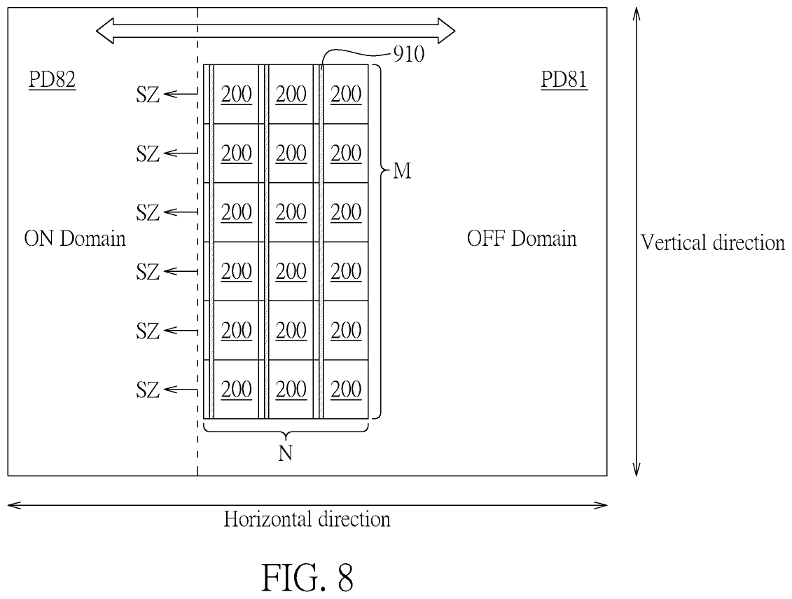

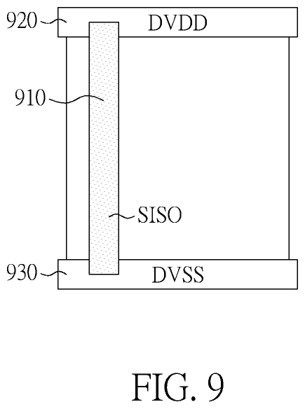

FIG. 8 illustrates a power domain PD81 and a power domain PD82 where an array of isolation circuits 200 is embedded in the power domain PD81. FIG. 9 illustrates a layout of the isolation circuit 200 used in the scenario of FIG. 8.

In FIG. 8, each of the isolation circuits 200 is embedded in the power domain PD81, and each of the result signals SZ is transmitted to a circuit in the power domain PD82. The power domain PD81 is switchable and can be powered off when the power domain PD82 is powered on. In other words, the power domains PD81 and PD82 can respectively be an OFF domain and an ON domain.

As shown in FIG. 8, the first power domain PD81 and the second power domain PD82 are placed along a horizontal direction. As shown in FIG. 9, the isolation circuit 200 of FIG. 8 may include a first conductive portion 910 used to receive the isolation control signal SISO described in FIG. 2 to FIG. 4. The first conductive portion 910 may be routed along a vertical direction substantially perpendicular to the horizontal direction.

As shown in FIG. 9, the isolation circuit 200 of FIG. 8 may further include a second conductive portion 920 coupled to the power supply DVDD (mentioned in FIG. 2 to FIG. 4), and the second conductive portion 920 may be routed along the horizontal direction.

As shown in FIG. 9, the isolation circuit 200 of FIG. 8 may further include a third conductive portion 930 coupled to the reference voltage source DVSS (mentioned in FIG. 2 to FIG. 4), and the third conductive portion 930 may be routed along the horizontal direction.

In FIG. 8 and FIG. 9, the first conductive portion 910 and the second conductive portion 920 may be formed on different conductive layers. For example, the first conductive portion 910 can be formed on a third metal layer while the second conductive portion 920 is formed on a first metal layer below the third metal layer.

As shown in FIG. 8 and FIG. 9, the array of the isolation circuits 200 may include N×M isolation circuits 200 including N columns and M rows of isolation circuits 200. The first conductive portions 910 of the isolation circuits 200 in the same column may be coupled to one another.

In summary, by means of the isolation circuit 200 provided by an embodiment, the number of transistors in an isolation circuit can be reduced. Conductive path(s) for connecting to an always-on power supply are no longer required and need not be routed, thus less conductive portions and layers are required. A plurality of isolation circuits 200 can be tiled as an array, embedded in an OFF domain and used to transmit signals to an ON domain to avoid functionality failure and high leakage current. The problem of congestion in the place-and-route process can be reduced. The area and conductive path lengths of a chip can be also decreased. According to experiments, the chip area can be reduced by 38%, and conductive path lengths can be decreased by 36%. Hence, solutions to mitigate problems in the field are provided.

Those skilled in the art will readily observe that numerous modifications and alterations of the device and method may be made while retaining the teachings of the invention. Accordingly, the above disclosure should be construed as limited only by the metes and bounds of the appended claims.

1. An isolation circuit comprising:
an inverter comprising an input terminal configured to receive an input signal, an output terminal configured to output an output signal according to the input signal, and a power terminal coupled to a power supply, wherein the output signal is complementary to the input signal; and
a NOR-gate configured to perform a logical NOR operation using the output signal and an isolation control signal to generate a result signal, the NOR-gate comprising a first input terminal coupled to the output terminal of the inverter and configured to receive the output signal, a second input terminal configured to receive the isolation control signal, and an output terminal configured to output the result signal;
wherein the isolation circuit is embedded in a first power domain, the result signal is transmitted to a circuit of a second power domain, and the first power domain is switchable to be powered off when the second power domain is powered on;
the first power domain and the second power domain are placed along a horizontal direction, the isolation circuit further comprises a first conductive portion configured to receive the isolation control signal, the first conductive portion is routed along a vertical direction substantially perpendicular to the horizontal direction, and is vertically aligned with first conductive portions of all other isolation circuits in a same column; and
the isolation circuit further comprises a second conductive portion coupled to the power supply, and the second conductive portion is routed along the horizontal direction, and is horizontally aligned with second conductive portions of all other isolation circuits in a same row.

2. The isolation circuit of claim 1, wherein the NOR-gate further comprises a first power terminal coupled to the power supply.

3. The isolation circuit of claim 2, wherein the NOR-gate further comprises a second power terminal coupled to a reference voltage source.

4. The isolation circuit of claim 2, wherein the power supply is switchable instead of being always on.

5. The isolation circuit of claim 2, wherein the NOR-gate further comprises:
a first transistor comprising a first terminal coupled to the power supply, a second terminal, and a control terminal coupled to the second input terminal of the NOR-gate;
a second transistor comprising a first terminal coupled to the second terminal of the first transistor, a second terminal coupled to the output terminal of the NOR-gate, and a control terminal coupled to the first input terminal of the NOR-gate;
a third transistor comprising a first terminal coupled to the output terminal of the NOR-gate, a second terminal, and a control terminal coupled to the first input terminal of the NOR-gate; and
a fourth transistor comprising a first terminal coupled to the output terminal of the NOR-gate, a second terminal, and a control terminal coupled to the second input terminal of the NOR-gate.

6. The isolation circuit of claim 5, wherein the NOR-gate further comprises a second power terminal coupled to a reference voltage source, the second terminal of the third transistor is coupled to the second power terminal of the NOR-gate, and the second terminal of the fourth transistor is coupled to the second power terminal of the NOR-gate.

7. The isolation of claim 5, wherein the first transistor and the second transistor are P-type transistors, and the third transistor and the fourth transistor are N-type transistors.

8. The isolation circuit of claim 1, wherein:
the result signal is at a low voltage level when the input signal is at the low voltage level and the isolation control signal is at the low voltage level.

9. The isolation circuit of claim 1, wherein:
the result signal is at a high voltage level when the input signal is at the high voltage level and the isolation control signal is at a low voltage level.

10. The isolation circuit of claim 1, wherein:
the result signal is at a low voltage level when the isolation control signal is at a high voltage level.

11. (canceled)

12. An isolation circuit comprising:
an inverter comprising an input terminal configured to receive an input signal, an output terminal configured to output an output signal according to the input signal, and a power terminal coupled to a power supply, wherein the output signal is complementary to the input signal; and
a NOR-gate configured to perform a logical NOR operation using the output signal and an isolation control signal to generate a result signal, the NOR-gate comprising a first input terminal coupled to the output terminal of the inverter and configured to receive the output signal, a second input terminal configured to receive the isolation control signal, and an output terminal configured to output the result signal;
wherein the isolation circuit is embedded in a first power domain, the result signal is transmitted to a circuit of a second power domain, and the first power domain is switchable to be powered off when the second power domain is powered on;
the first power domain and the second power domain are placed along a vertical direction, the isolation circuit further comprises a first conductive portion configured to receive the isolation control signal, the first conductive portion is routed along a horizontal direction substantially perpendicular to the vertical direction, and is horizontally aligned with first conductive portions of all other isolation circuits in a same row; and
the isolation circuit further comprises a second conductive portion coupled to the power supply, and the second conductive portion is routed along the horizontal direction, and is horizontally aligned with second conductive portions of all other isolation circuits in a same row.

13. (canceled)

14. The isolation circuit of claim 12, wherein the first conductive portion and the second conductive portion are formed on different conductive layers.

15-16. (canceled)

17. The isolation circuit of claim 1, wherein the first conductive portion and the second conductive portion are formed on different conductive layers.

18. The isolation circuit of claim 1, wherein the inverter further comprises:
a first transistor comprising a first terminal coupled to the power terminal of the inverter, a second terminal coupled to the output terminal of the inverter, and a control terminal coupled to the input terminal of the inverter; and
a second transistor comprising a first terminal coupled to the output terminal of the inverter, a second terminal, and a control terminal coupled to the input terminal of the inverter.

19. The isolation circuit of claim 18, wherein the first transistor of the inverter is a P-type transistor, and the second transistor of the inverter is an N-type transistor.
